(19) United States
(12) Patent Application Publication
(10) Pub. No.: US 2025/0036824 A1
(43) Pub. Date: Jan. 30, 2025

(54) SYSTEMS AND METHODS FOR MOBILE DATA CAPTURE AND 3D MODEL CONSTRUCTION

(71) Applicant: LiMAR AI Inc., San Diego, CA (US)

(72) Inventors: Dominique E. MEYER, San Diego, CA (US); Filip PIEKNIEWSKI, San Diego, CA (US); Lukas FRASER, Fredericton (CA); Alex GRANT, San Diego, CA (US); Jonathan KLINGSPON, Carlsbad, CA (US); Todd HYLTON, La Jolla, CA (US); Shreyas NIRADI, San Diego, CA (US)

(73) Assignee: LiMAR AI Inc., San Diego, CA (US)

(21) Appl. No.: 18/786,390

(22) Filed: Jul. 26, 2024

Related U.S. Application Data
(60) Provisional application No. 63/516,449, filed on Jul. 28, 2023.

(51) Int. Cl. G06F 30/13

(52) U.S. Cl. CPC G06F 30/13

(57) ABSTRACT

Disclosed herein are systems and methods for mobile data capture and 3D model construction. The system may comprise four major subsystems: capture system hardware that captures data of the infrastructure, capture system software that controls the capture system hardware by determining one or more parameters for capturing the data, model construction software that reconstructs the captured data into one or more model representations, and model analysis software that extracts one or more features of the one or more model representations.

### CROSS-REFERENCE TO RELATED APPLICATION

This application claims the benefit of U.S. Provisional Application No. 63/516,449, filed Jul. 28, 2023, the entire contents of which are hereby incorporated by reference herein.

### FIELD OF THE DISCLOSURE

This disclosure relates generally to systems and methods for mobile data capture and 3D model construction.

### BACKGROUND OF THE DISCLOSURE

Capturing and creating 3D models of a physical environment is known to be difficult, slow, and expensive. For example, lidar systems are constructed of lasers that output directed light pulses, sensors that detect the reflection of these pulses from surfaces, and a motorized mechanical system that sweeps the orientation of the laser and sensors to capture 3D information. In this way, lidars capture a representation of the environment as a collection of points (e.g., azimuth, elevation, and distance from the lidar) known as a “point cloud.” While effective in achieving accurate measurements of distance, lidars suffer from sparsity in the collected points, lack of accurate color information, mechanical frailty, the need for substantial user expertise, high device cost, and large data file sizes. The net effect of these limitations is that 3D models captured with lidar are limited to application niches, where highly accurate distance measurement is of very high value and where skilled personnel are available to capture and process the data. Most of the human-built world (e.g., buildings, roads, power infrastructure, water infrastructure) are not well-served by lidar mapping technologies and, correspondingly, there are very few 3D models of the environment that we inhabit and depend on. In general, this lack of 3D information inhibits cost-effective and accurate maintenance, evaluation, and improvements of the human-built world. For example, in the case of building construction, general contractors seek to minimize discrepancies between design and build, so creating 3D models allows them to find such mistakes early and fix them while the costs to do so are still small. In another example, in surveying of powerline infrastructure, creating 3D models of utility poles and lines enables assessment of the forces on the poles, the safety and compliance of the spacing of the conductors, the risks from vegetation encroachment, and an assessment of health of the electrical components. In another example, in the installation of underground pipes and conduits for water, fuels, power, and communications, creating 3D models of the infrastructure before it is buried allows accurate determination of the location of that infrastructure when it is no longer visible from the surface.

A goal may be to overcome the technical and cost limitations of today's 3D data capture and model creation solutions and, thereby, to support the entire lifecycle of built-world assets with affordable, detailed, accurate 3D models sufficient for almost any engineering, surveying, modeling, and assessment task. Such abilities may transform the ability to build and service the infrastructure that supports us all.

### BRIEF SUMMARY OF THE DISCLOSURE

Disclosed herein is a whole-system, end-to-end approach deploying novel data capture and data processing technology that addresses the limitations of prevailing solutions (e.g., lidar based systems). The system may comprise four major subsystems: capture system hardware that captures data of the infrastructure, capture system software that controls the capture system hardware by determining one or more parameters for capturing the data, model construction software that reconstructs the captured data into one or more model representations, and model analysis software that extracts one or more features of the one or more model representations. A user may interact with the model analysis software. According to some examples, a system for creating a 3D model representation of a scene is disclosed. The system comprises: capture system hardware configured to capture data of the scene using at least a plurality of cameras; capture system software configured to control the capture system hardware by determining one or more parameters for capturing the data; model construction software configured to construct one or more model representations using the captured data and information about the capture system hardware; and model analysis software configured to extract one or more features of the one or more model representations and create the 3D model representation of the scene, wherein the 3D model representation of the scene comprises the one or more extracted features. Additionally or alternatively, in some examples, the capture system hardware comprises: a camera frame assembly that maintains positions and orientations of the plurality of cameras with respect to each other; and a time controller that synchronizes capturing of image data by the plurality of cameras. Additionally or alternatively, in some examples, the model construction software is configured to: build one or more maps representative of location and orientation of the system within the scene wherein the one or more maps are used to create the 3D model representation of the scene. Additionally or alternatively, in some examples, the plurality of cameras comprises a first camera facing forward, a second camera facing upward, a third camera facing left, and a fourth camera facing right. Additionally or alternatively, in some examples, the system further comprises: a mount configured to attach the capture system hardware to a handle or a pole; and a display configured to be mounted on the rear of the capture system hardware. Additionally or alternatively, in some examples, the system further comprises: a plurality of lights surrounding the plurality of cameras, the plurality of lights configured to illuminate the scene during image capture. Additionally or alternatively, in some examples, the capture system hardware comprises a time controller configured to control the plurality of lights during image capture based on one or more of: a brightness of the scene, a motion of the scene, a battery power, and user experience. Additionally or alternatively, in some examples, the system further comprises: one or more location sensors configured to determine location and orientation information of the system, wherein the one or more location sensors comprise one or more of: a satellite geolocation sensor (GPS) or an inertial measurement unit (IMU) sensor. Additionally or alternatively, in some examples, the system comprises an onboard computer configured for image capture, sensor data capture, and processing image and sensor data. Additionally or alternatively, in some examples, the capture system software is configured to: receive input data comprising one or more of: sensor inputs, user inputs, and prior image data; and control one or more of the plurality of cameras and one or more lights during image capture based on the received input data. Additionally or alternatively, in some examples, the system further comprises: a transceiver configured to receive information from a WiFi connection, a cellular connection, or real-time GPS correction services, wherein the received information is used by the capture system software to improve estimations of locations and orientations of the plurality of cameras. Additionally or alternatively, in some examples, the capture system software is configured to provide input for controlling movements of a robot, or for providing information to an operator of the robot for controlling the movements of the robot. Additionally or alternatively, in some examples, the model construction software comprises a feature extraction algorithm configured to identify features within images represented by the captured data. Additionally or alternatively, in some examples, the model construction software comprises a feature matching algorithm configured to identify common features in different images of the scene. Additionally or alternatively, in some examples, the model construction software comprises a mapping algorithm configured to: receive the identified common features of the scene and the information corresponding to the captured data; determine 3D positions and orientations of the plurality of cameras during image capture; and determine 3D positions of the identified common features of the scene. Additionally or alternatively, in some examples, the model construction software constructs a 3D point cloud representation of the scene from the 3D positions of the identified common features of the scene model construction software; wherein the model construction software is further configured to: construct one or more projected 2D representations using the 3D point cloud representation and the captured data; or identify and match common features across captured images using the 3D point cloud representation and information about the capture system hardware during image capture. Additionally or alternatively, in some examples, the model construction software comprises a 2D image segmentation and classification algorithm that identifies objects in 2D images and labels pixels of the 2D images with information pertaining to features of the identified objects, wherein the pixel labels are propagated to corresponding points in a 3D point cloud representation of the scene. Additionally or alternatively, in some examples, the model analysis software is configured to receive user input, wherein the extraction of the one or more features of the one or more model representations is based on the user input. Additionally or alternatively, in some examples, the user input comprises inputs related to one or more of: segmentation, classification of features, labeling, feature information, or object information.

A computer-implemented method for creating a 3D model representation of a scene is disclosed. The method comprises: capturing data of the scene using a plurality of cameras of a capture system hardware; receiving information about the capture system hardware; constructing one or more model representations using the captured data and received information; extracting one or more features of the one or more model representations; and creating the 3D model representation of the scene, wherein the 3D model representation of the scene comprises the one or more extracted features.

### BRIEF DESCRIPTION OF THE DRAWINGS

The patent or application file includes at least one drawing executed in color. Color copies of this patent or patent application publication with color drawings will be provided by Office upon request and payment of the necessary fee.

FIG. 1 illustrates a block diagram of an example system, according to some embodiments of the disclosure.

FIG. 2 illustrates an example capture system device image and hardware architecture, according to some embodiments of the disclosure.

FIG. 3 illustrates a schematic of the exterior of an example system hardware, according to some embodiments of the disclosure.

FIG. 4 illustrates a schematic of an example camera frame assembly, according to some embodiments of the disclosure.

FIG. 5 illustrates a block diagram of an example architecture of the capture system software, according to some embodiments of the disclosure.

FIG. 6 illustrates a block diagram of an example model construction software system architecture, according to some embodiments of the disclosure.

FIGS. 7A and 7B illustrate three dimensional representation of a scene and an example segmentation of a scene into various object or asset classes and its rendering into classes, according to some embodiments of the disclosure.

FIG. 8 illustrates a block diagram of an example model analysis software, according to some embodiments of the disclosure.

FIG. 9 illustrates example analytics provided by the model analysis software and associated evaluation and analysis software, according to some embodiments of the disclosure.

FIG. 10 illustrates an example user workflow, according to some embodiments of the disclosure.

FIG. 11 illustrates a block diagram of an exemplary system, according to some embodiments of the disclosure.

### DETAILED DESCRIPTION

Disclosed herein are systems and methods for mobile data capture and 3D model construction. The disclosed systems and methods may comprise an end-to-end hardware-software solution that is entirely automated. The system and methods disclosed herein may allow construction of the model representations without requiring a user to curate data and/or tweak parameters to create accurate model representations.

The following description is presented to enable a person of ordinary skill in the art to make and use various embodiments. Descriptions of specific devices, techniques, and applications are provided only as examples. These examples are being provided solely to add context and aid in the understanding of the described examples. It will thus be apparent to a person of ordinary skill in the art that the described examples may be practiced without some or all of the specific details. Other applications are possible, such that the following examples should not be taken as limiting. Various modifications in the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

Various techniques and process flow steps will be described in detail with reference to examples as illustrated in the accompanying drawings. In the following description, numerous specific details are set forth in order to provide a thorough understanding of one or more aspects and/or features described or referenced herein. It will be apparent, however, to a person of ordinary skill in the art, that one or more aspects and/or features described or referenced herein may be practiced without some or all of these specific details. In other instances, well-known process steps and/or structures have not been described in detail in order to not obscure some of the aspects and/or features described or referenced herein.

In the following description of examples, reference is made to the accompanying drawings which form a part hereof, and in which, by way of illustration, specific examples are shown that can be practiced. It is to be understood that other examples can be used, and structural changes can be made without departing from the scope of the disclosed examples.

The terminology used in the description of the various described embodiments herein is for the purpose of describing particular embodiments only and is not intended to be limiting. As used in the description of the various described embodiments and the appended claims, the singular forms “a,” “an,” and “the” are intended to include the plural forms as well, unless the context clearly indicates otherwise. It will also be understood that the term “and/or” as used herein refers to and encompasses any and all possible combination of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

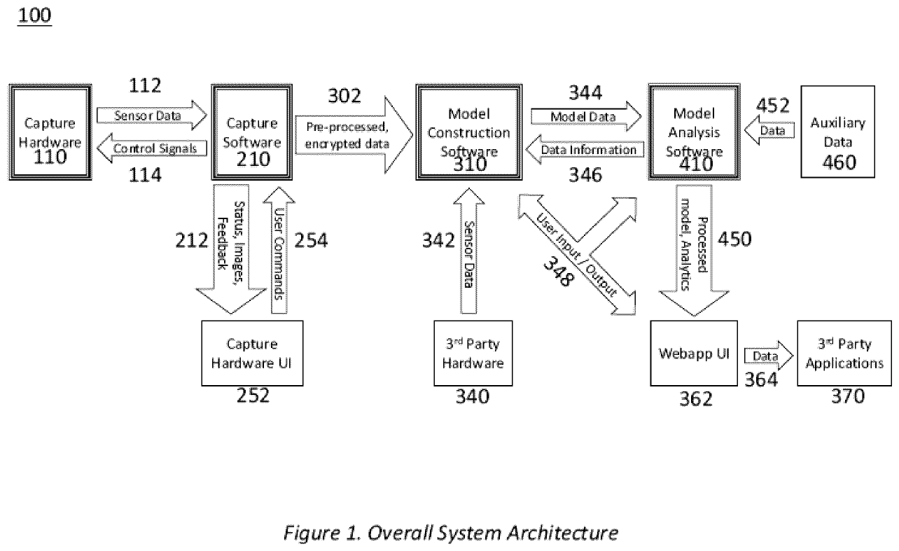

The invention is a system for data capture and processing to create geometrically accurate, georeferenced 3D model representations of the world and human-built infrastructure. FIG. 1 illustrates a block diagram of an example system 100 comprising four major subsystems: capture system hardware 110, capture system software 210, model construction software 310, and model analysis software 410 (discussed in more detail below).

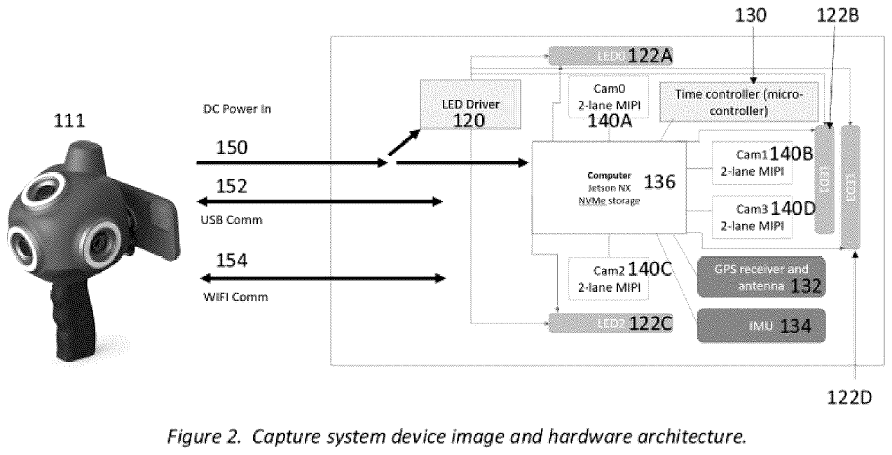

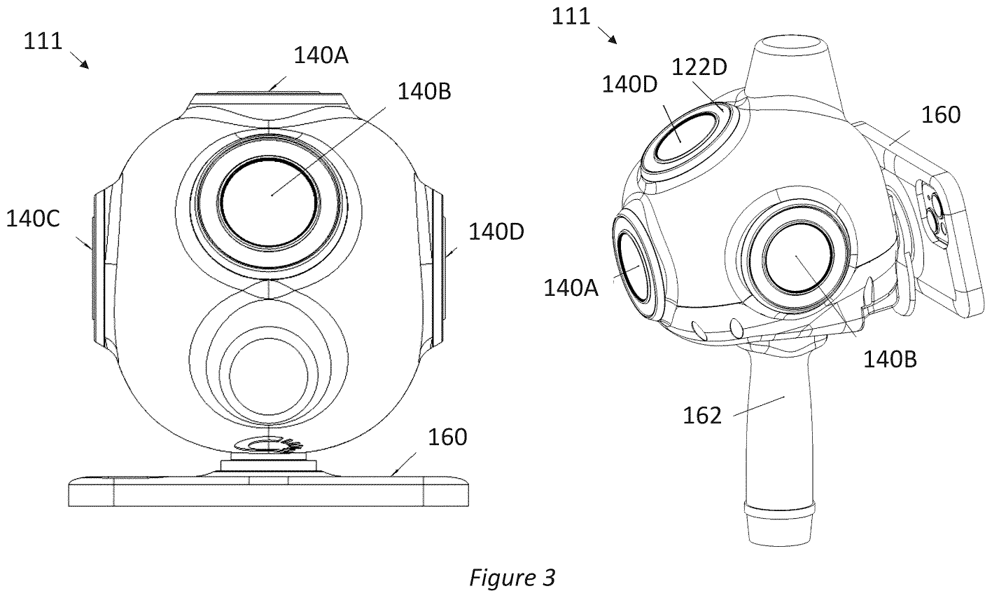

Capture system hardware 110: Data 112 is captured by an integrated hardware system and associated firmware. The capture system hardware 110 comprises an array of cameras 140, that face outward and that are physically spaced by a certain amount. In some aspects, the amount of spacing is such that the scene is completely captured. In some aspects, the amount of spacing is such that multiple images with overlapping elements from different cameras and/or from different locations and directions are captured. The multiple images may be captured as the integrated hardware moves through a scene. This coverage and diversity of image perspectives supports the construction of complete, detailed, geometrically accurate 3D models of the scene. In some embodiments, the cameras are oriented predominantly in the forward, upward, left, and right directions. In some aspects, the capture system hardware 110 also includes a light system comprising a set of lights 122 and an LED driver 120, a time controller 130, an inertial measurement unit (IMU) 134, GPS sensor 132, and an on-board computer 136. FIG. 2 illustrates an example capture system device 111 and hardware architecture. In some aspects, the capture system device 111 may be coupled to a DC power in 150 to receive power. FIG. 3 illustrates a schematic of the exterior of an example capture system device 111. In some embodiments, the capture system device 111 comprises four cameras 140 facing different directions, such as a first camera 140A facing mostly forward, a second camera 140D facing mostly upward, a third camera 140B facing mostly left, and one camera 140C facing mostly right.

The following are example features, implementations, or applications of the capture system hardware 110. If used as a handheld device, as shown in FIG. 3, a handle (or pole) 162 may be attached to the bottom of the capture system device 111 via a mount, and a display 160 may be mounted on the rear of the capture system device 111. In some aspects, the display 160 may be integrated into the hardware package, or may be an attached display device, such as a mobile phone. The handle 162 may be short and held in a single hand, may be long or extending and held in one or two hands to position the cameras above barriers, or may be integrated with a backpack or other body mounting to facilitate usage. In use cases employing a handle 162, the capture system device 111 may be transported by a user. For example, the user may hold the handle 162 while walking around and through the area that the 3D model will represent. In some cases, the capture system device 111 may be mounted on a human-driven vehicle, a terrestrial robot, or an aerial drone. For example, if mounted to a car, the capture system device 111 may capture data for constructing 3D models of the environment in and around the roadway.

The display 160, whether attached to or detached from the rest of the capture system hardware 110, is used to communicate to the user information pertinent to correctly capturing the data. For example, the display 160 may provide images seen by the cameras 140, the status of the hardware sensors, a map of the area traversed by the user, the status of data captured thus far, and/or tips to guide the user to improve the quality of the data collected.

Cameras 140 may be oriented with a specific, fixed geometry to facilitate model construction by the software system. For example, a handheld device may orient the cameras predominantly in the forward, upward, left, and right directions to capture the scene in front of and/or around the user without capturing the user. Complete coverage of the scene may depend on the user orienting, pointing, and/or locating the camera along various locations (variably) during the capture of a scene. In some embodiments, a vehicular, roof-mounted device may orient cameras in predominant directions to capture 360 degree scene information surrounding the vehicle. In the case of imaging, e.g., a powerline, the scene comprises areas near the ground and in vegetation that have less light. The cameras may be configured to reconstruct with a longer exposure time when facing in the directions of the areas near the ground and/or in vegetation. While facing areas that are significantly brighter (e.g., in the direction of the sky), the exposure may be adjusted to be lower to be able to visibly observe the thin powerlines that are then reconstructed in 3d space.

Aspects of the disclosure may comprise a camera system capable of imaging different parts of a scene that may have different properties (e.g., brightness). As an example, when a camera system is used on a vehicle that is moving through an environment with different lighting conditions, the camera system may be configured to have a higher dynamic range when the camera system observes different parts of the scene. For example, when driving underneath a bridge, the camera system may be configured to see both areas in the sunlight that is not cast by the bridge's shadow, as well as parts of the bridge that are in shadows. Another example is when the camera system is being carried from inside to outside of the building, and vice versa. At the doorway, the camera system may see a much darker interior of the facility, as well as the exterior. The camera system may be configured with a dynamic range that supports changing the range suitable for both the interior scene and the exterior scene, to ensure correct visibility of all features in the scene and to ensure reliable reconstruction.

Aspects of the disclosure may comprise cameras 140 with global shutters to improve image capture and synchronization. In some aspects, cameras 140 having a high dynamic range may be used to support a broad variety of lighting conditions. For example, the brightness of a scene may vary from place to place such that amount of ambient light available for image capture may vary substantially. For example, in the data capture of a building, the exterior regions of the capture may be lit by bright sunlight while the interior regions may be unlit or poorly lit by ambient or electric lights. Cameras with high dynamic range may help allow high quality image capture in a variety of lighting conditions, thereby reducing or avoiding under or overexposed images (which might degrade the quality of 3D models constructed from them). In some aspects, the dynamic range may be between 120-140 dB, e.g., to capture scenes in both dark and sunlight exteriors concurrently. In some examples, cameras 140 having a high resolution may be used to create more detailed model representations. For example, resolutions greater than 5 million pixels per camera may be desired for applications entailing 3D models of infrastructure like power lines, roadways, bridges, parking lots, buildings, construction sites, mines, and pipelines. In aspects, the capture system hardware 110 may comprise cameras 140 and lenses that have been previously calibrated to remove distortion and refine geometry of the capture system hardware 110, for example the relative pose of the cameras.

The lighting system may be configured such that lights 122 are located in correspondence with the camera 140 locations on the capture system hardware 110 to best illuminate the field of view of the cameras 140. For example, as shown in FIG. 3, the capture system device 111 comprises light 122D that is located in correspondence with the camera 140D. Additionally or alternatively, the capture system device 111 comprises light 122A, light 122B, and light 122C that are located in correspondence with camera 140A, 140B, and 140C, respectively. The lights 122 may be light emitting diodes (LEDs), halogen or xenon located in the chassis between or around the sensors and lenses. In some aspects, the sensor, lenses, and lights can cover visible and/or non-visible spectrum. In some aspects, lights 122 may change in brightness while not turning off fully to limit effect on human visibility. Lights and sensors may be simultaneously triggered. For example, lights and sensors may be simultaneously triggered in applications where ambient light levels are low. It may be desirable to reduce power consumption to preserve battery life and extend capture time, and/or it may be desirable to illuminate with an intensity higher than can be achieved if the lights are on but not strobed. Example applications may include, but are not limited to, a darker setting such as during nighttime being outside, in a partial coverage area such as the side of a building, fully inside (even when the interior lights of the facility are on because those are often still too dark), etc. In some aspects, the intensity of the lights 122 may change (increase or decrease) while sensors are capturing data. The lights 122 may be used to control exposure of the sensor, for example, during a rolling shutter or global reset. In the case of a rolling shutter sensor, the intensity of the lights may change before or after the first sensor row exposure.

In some examples, the light intensity may be varied according to other sensor inputs, user inputs, or prior image data (e.g., prior image captures, prior image estimates of camera location and orientation, etc.). For example, if an inertial sensor detects that camera is moving at higher speed, the camera system may be configured to decrease the image sensor exposure time and/or increase the light intensity to ensure that the images are not blurred and remain adequately illuminated. In some aspects, if the camera system detects that recent prior images are under illuminated, the camera system may be configured to increase the intensity of lights to mitigate this effect or compensate for the under illumination. Depending on the distance of the camera to the object, in some cases, for example, an object, such as a manhole with less light or a warehouse or outside road, may need a lot more light. The proximity of the camera to the object/area that is being imaged may make a difference. Since the flux of light falls off quadratically (1/r²), the amount of light needed may depend on the object or scene being imaged. For example, a lot less light may be needed when imaging a manhole that is only 30 cm-100 cm from the camera, than when imaging a warehouse that is 10-30 m from the camera. To increase the accuracy of the data and/or to increase the quality of the images captured, the camera system may be configured to continuously adjust both exposure time and the amount of light the is being emitted into the scene by the camera system.

For example, if the lights are strobed on and off with the camera capture, the very large intensity change may be uncomfortable for the person using the device. To mitigate this effect, the lights need not be turned off completely, but instead examples of the disclosure include turning the lights to a lower level of intensity. A lower intensity level may suppress the effects on the user while also using less energy, which may, in some aspects, be important for battery powered operation. Another example relates to a manhole/vault. When a camera is taken into a manhole/vault, the exposure may lengthen to be able to capture the darker environment. Additionally or alternatively, when the user points the camera in a different direction (e.g., down) this may result in a change in exposure. Yet another example relates to changing from an outside environment to an inside environment. When outside (in sunlight), the camera exposure is lower to ensure that the pixels are not saturated. This results in a change in exposure that is controlled by the auto-exposure of the disclosed camera system.

The lights 122 may be coupled to an LED driver 120. The LED driver 120 may be configured to activate the lights 122, for example, when there may be insufficient ambient light to capture high quality images. In some embodiments, the LED driver 120 may strobe in synchrony with the camera shutters to apply light only during image capture. This strobing may, for example, be more energy efficient and may permit brighter illumination during the image capture.

The capture system hardware 110 may comprise a time controller 130. The time controller 130 determines when to capture images and, in some embodiments, when to strobe the lights 122 with the LED driver 120. The timing may be based on, for example, the brightness of the scene, the motion of the camera through scene, the battery power levels, or the user's experience. In some examples, the timer of the time controller 130 may be based on a fixed frequency to optimize the efficiency of the data capture and the coverage of the scene as needed to construct 3D representations of the scene.

The capture system hardware 110 is equipped with one or more location sensors (e.g., IMU 134, GPS sensor(s) 132) to capture location and orientation information of the capture system hardware 110. In some examples, images and location and orientation information may be captured simultaneously. This simultaneous capture of the images along with the location and orientation information may aid in the construction of the model representations from the captured data. In some embodiments, it may be helpful to capture data non-simultaneously from various sensors. For example, the camera system may be configured to capture IMU and GPS data more frequently than camera data. The increased amount of IMU and GPS data may support better estimation of the hardware system location and orientation, which may be beneficial in determining when to trigger camera data capture and in constructing 3D models from that data. In some examples, capturing IMU data more frequently may help with Kalman filter pose estimation to provide continuity for when images are captured. Additionally or alternatively, in some aspects, certain sensors (e.g., IMU) can generate data faster. This data can be used to interpolate the trajectory, for a less frequently sampled image or GPS data, for example. In the case that the image capture is paused or stopped, the IMU data may continue capturing data. This makes it possible to leverage different sensory benefits at different times. Additional location and orientation information may be collected before, between, and/or after image collection. This data may aid in providing feedback to the user and in the construction of model representations. The feedback may be used, for example, by the user to visualize the location and orientation of the hardware system on a map on the display. The information may be used to assess the completeness of the intended data capture of a scene. The information may indicate how well the space/area/object has been captured, and/or the derivative accuracy that is expected from the model. For example, when capturing an indoor facility, it may show the path of the users, and possible areas that were poorly captured (e.g., camera system moved too fast, camera system too far away). Additionally or alternatively, the information may indicate the areas that have been captured well. In the case of outdoor capture, the map may show a path of the trajectory, as well the quality of coverage of, for example, the electric poles. The GPS sensor 132 may be capable of receiving real-time or post-processed timing corrections to obtain more accurate positioning information.

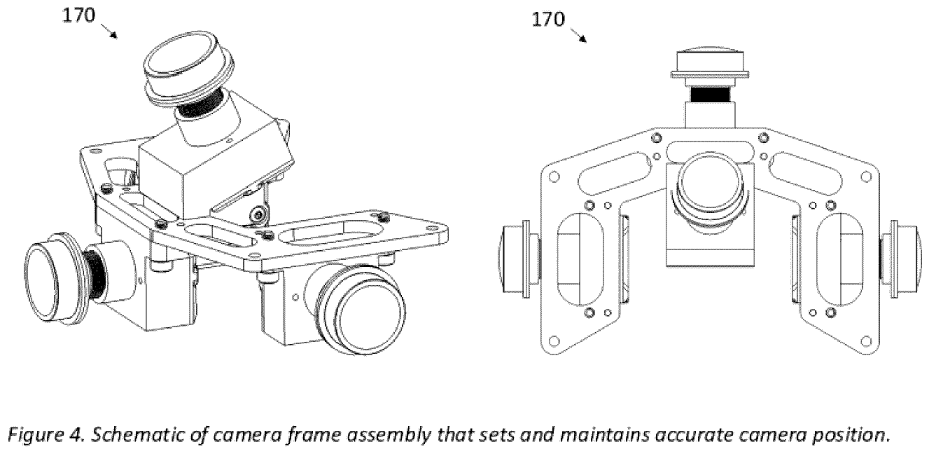

FIG. 4 illustrates a schematic of an example camera frame assembly 170. The camera frame assembly maintains precise and consistent camera orientations, which may be critical to the construction of 3D models from the camera images. The geometry of the cameras may be critical to the construction of 3D representations from captured images because the photogrammetry algorithms in the model construction software triangulate on common features in different images to compute distance. Accurate triangulation requires accurate and precise knowledge of the positions of the cameras relative to each other. In some aspects, the camera frame assembly orients and positions the cameras to optimize the overlap of simultaneously captured images. Along with the field of view of the cameras, this orientation and positioning are optimized to efficiently capture the scene and to match image features across different cameras in the assembly. In some examples, the camera frame assembly may be constructed of rigid and durable materials to maintain camera positions and orientations relative to each other. The camera frame assembly may expand or contract depending on temperature, and knowledge of this temperature can be used to compute this effect (from expansion/contraction) and to inform the photogrammetric portions of the model construction software. Embodiments of the disclosure include estimating mechanical distortion from thermal change.

Capture system software 210: The capture system hardware 110 is controlled by the capture system software 210 using control signals 114. The capture system software 210 may determine one or more parameters for capturing the data (e.g., when to capture images given previous motion, location, and/or scene geometry). Image capture by the cameras 140 and illumination by lights 122 may be triggered by an optimization algorithm. The optimization may combine information from some or all of: IMU 134 measurements, GPS location, prior images (prior scene information 220), and/or externally provided scene information such as maps in order to optimize the efficiency of data capture and the quality of subsequent representations such as 3D models. The capture system software 210 communicates status, images, and feedback 212 with capture hardware UI 252, and receives user commands 254 from it to initiate, modify, and terminate activities in the capture system software 210.

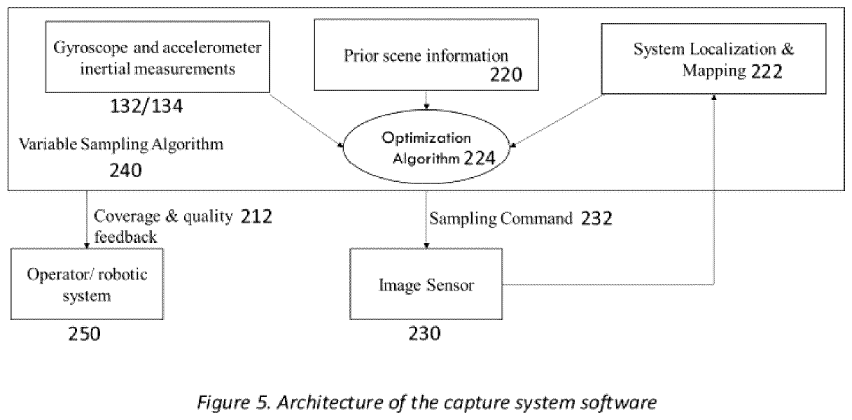

FIG. 5 illustrates a block diagram of an example architecture of the capture system software 210. The following are example features, implementations, or applications of the capture system software 210. Optimization algorithms 224 implemented on the capture system hardware 110 can be used to both create maps in real time and to determine the position of the capture system hardware 110 within the map. The system localization and mapping 222 (comprising the maps and localization) can provide feedback to the hardware operator (e.g., human, vehicle, and/or robot) about the quality of the data capture and inform the triggering of the data capture hardware. Previous camera calibration may be used to improve the performance of these algorithms. Example algorithms may include, but are not limited to, simultaneous localization and mapping (SLAM), Structure from Motion, Photogrammetry, or Visual Odometry algorithms. If the capture system hardware 110 has access to the internet, the capture system software 210 may stream data to the cloud or external compute resources to complete a hybrid or remote localization. This data may include image/video stream, GPS data, IMU data, estimated position and orientation, accuracy estimates, etc. If the capture system hardware 110 has access to the internet (using a transceiver), for example, via a WiFi or cellular connection 154 (or real-time GPS correction services), then GNSS timing correction data can be streamed to the capture system hardware 110 to supplement and improve the location accuracy of the onboard GPS sensor. In some aspects, other locally available position information, from WiFi signals, cellular signals, ground reference points can be used to determine or supplement the geolocation accuracy of the on-board capture system sensing hardware.

In some aspects, the variable sampling algorithm 240 may deploy different rates of data capture from the sensors depending on information from one or more of: the GPS sensor 132, IMU 134, prior scene information 220, system localization and mapping 222, and optimization algorithms 224. The information may be used to optimize data collection completeness and cost. If the hardware system is mounted on a robot 250, then coverage and quality feedback 212 may to be used to directly control the movements of the robot or inform the actions of an operator controlling the robot. In some aspects, the capture system software may provide input for controlling the robot.

A data triggering event may synchronize the capture of some or all the image sensors 230 and cameras 140 of the capture system hardware 1140, where the collection of synchronized image data at a certain timestamp may be denoted as a “snapshot.” This synchronization of the capture of the sensors 230 and cameras 140 improves the accuracy of representations of 3D models. If the scene is too dark to be effectively captured without illumination, the capture system software 210 triggers the onboard illumination devices (lights 222) in synchrony with the data capture hardware. Pulsing of the lighting systems improves battery life and increases illumination intensity (as compared to statically illuminating the scene with a constant light source).

In some aspects, preliminary processing may be performed on the capture system processor to: reconstruct a low-resolution 2D or 3D map that shows what areas have been covered, compress the data to minimize the footprint to transfer the data to the cloud, and/or encrypt and filter data for security and privacy.

The captured sensor data (from the IMU(s) 134, image data from the cameras 140, and/or from the GPS sensor(s) 132) is transferred from the capture system hardware 110 and/or capture system software 210 to the cloud or local server via USB communication 152, WiFi communication 154, LTE, or SD card copy.

Model construction software 310: After transfer to the cloud or local server from the capture system, the images, IMU data, and GPS data (included in pre-processed, encrypted data 302) are reconstructed into one or more model representations, e.g., semantically classified 3D point clouds, 3D meshes, 3D textured meshes, 3D immersive visualization using neural radiance fields and other methods, panoramas, 2D projections and ortho-projections, 2D cross sections, 2D contours, and various means to segment and highlight selected features within the model presentations. The construction of these model representations follows a multi-stage processing architecture.

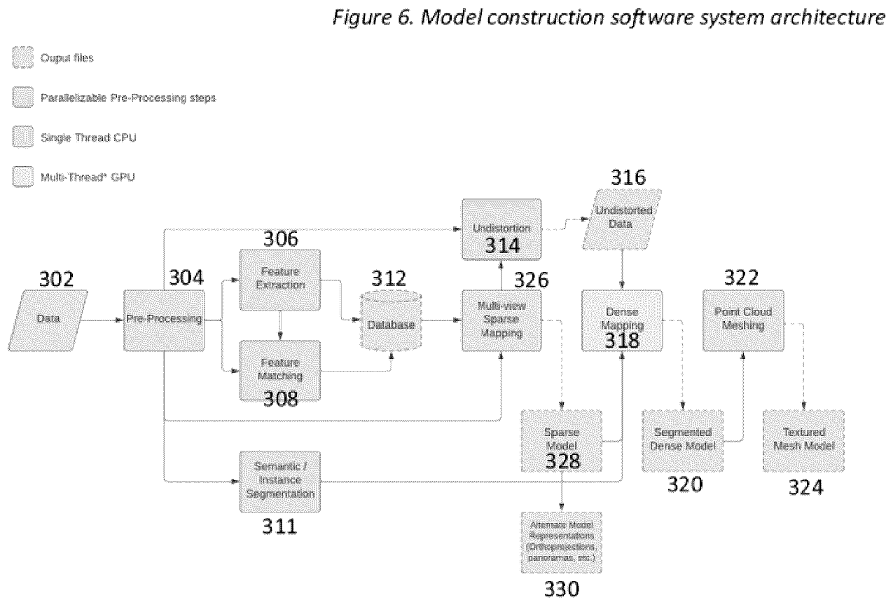

FIG. 6 illustrates a block diagram of an example model construction software system architecture. The feature extraction 306 algorithm locates distinctive features within images that are used to match to the same features among different images using a feature matching 308 algorithm. For example, a prominent corner on a building can be a distinctive feature that is easily located and matched among different images containing that corner. The multi-view sparse mapping 326 algorithm may use feature matching data 308, feature extraction data 306, and metadata from the pre-processing algorithm 304 to determine camera locations and orientations at the time of camera image captures. This camera location and orientation information is used by the sparse model algorithm 328 to determine the 3D location of the matched features 308 in the images. This sparse model information is used by the alternate model representations algorithm 330 to generate additional model representations such as orthographic projections and panoramic images. In some aspects, undistortion algorithm 314 removes known distortions in images caused by lens and other camera non-idealities. For example, if the images are distorted near the edges, an algorithm can be used to correct that distortion. The sparse model information 328 and the undistorted data 316 are used by dense mapping algorithm 318 to find additional, fine-scale, feature matches in images and their 3D positions to create a more highly detailed model.

The following are example features, implementations, or applications of the model construction software 310. In some aspects, images (included in data 302) are pre-processed in a pre-processing step 304 to compensate for lens distortion, brightness inconsistency, vignetting, and image noise removal. In addition to pre-processed, encrypted data 302 from the capture software 210, the model construction software 310 may receive sensor data 342 from other third-party hardware 340. For example, third-party hardware 310 may supply sensor data 342 may include laser scanning systems, GPS stations, or images from drones and manned aircraft.

The position and orientation of the capture system hardware 110 for one or more (e.g., each) capture events are determined using some or all available sensor information (images captured by camera(s) 140, IMU(s) 134, and GPS sensor(s) 132), a process that may be referred to as “structure from motion.” In some embodiments, a relatively rigid geometry of the cameras 140 within the capture system hardware 110 improves this process by constraining the per-snapshot position estimation and by providing a known metric scale. The integration of the capture system hardware 110, capture system software 210, and model construction software 310 enables the construction of much more efficient and accurate large-scale models at low-cost compared to competing technologies. Following the structure from motion phase, the images are densely mapped in step 318 via a “multi-view stereo algorithm” to extract a dense set of points composing a “dense point cloud” that comprises spatial information of the captured scene. To compress the representation and improve visualization, the dense point cloud may be fitted to a mesh (point cloud meshing 322) representing the surfaces of the scene, e.g., using a segmented dense model 320. To improve visualization, the mesh may be classified (e.g., by colorizing) by projecting (color) information from the original images onto the mesh. Such a representation may be referred to as a “textured mesh,” and may use a textured mesh model 324. Deep learning algorithms, such as deep convolutional neural networks or transformer networks, may be used to detect or segment objects/features within the original 2D images. This information may be projected into any of the 3D model representations, given the known correspondence of the 2D images and the 3D representations. For example, the segmentation algorithm may be used to segment an image into features such as “road,” “person,” or “car.” One or more (e.g., each) of these detected classes may be propagated into the 3D representations and classified (e.g., colored) accordingly. For example, roads may be colored a first color (blue), people colored a second color (green), and cars colored a third color (red). Such 3D model representations may be referred to as “segmented point clouds.”

Scene analysis can combine image-based semantic and instance segmentations 311 into a database 312 of classes, objects, features, states, conditions, which may serve applications. For example, the analysis could generate the condition of all segmented objects or areas that have a certain property (e.g., comprise hazards, are highly valuable, etc.).

The steps shown in the architecture of FIG. 6 may be classified as: input files (data 302), output files (database 312, undistorted data 316, sparse model 328, alternate model 330, segmented dense model 320, textured mesh model 324), parallelizable pre-processing steps (pre-processing 304, feature extraction 306, feature matching 308, semantic/instance segmentation 311, undistortion 314), single thread CPU (multi-view sparse mapping 326, point cloud meshing 322), or multi-thread CPU (dense mapping 318).

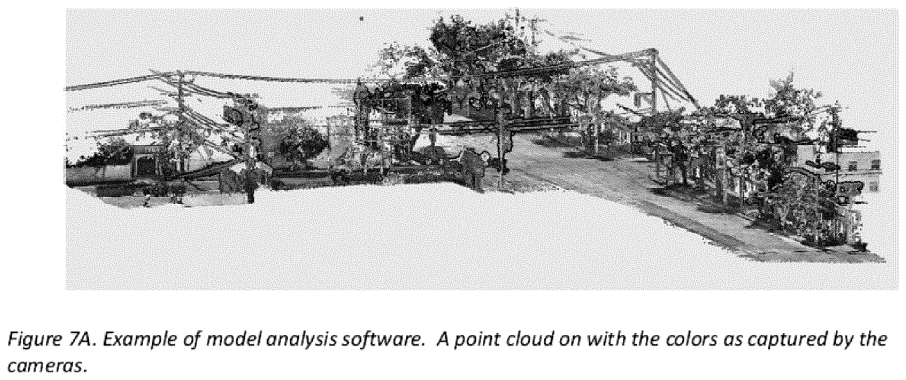

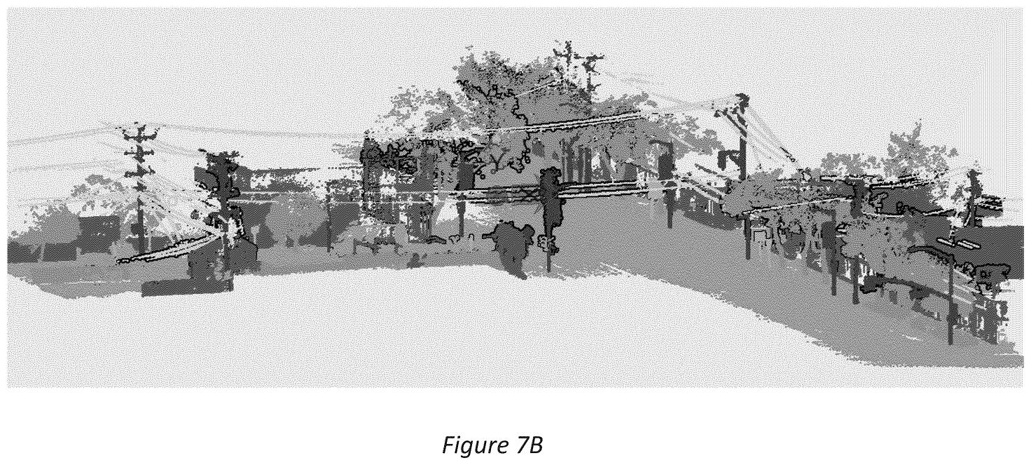

FIGS. 7A and 7B illustrate an example of the model analysis software. FIG. 7A illustrates an example of the model analysis software, with a point cloud on with the colors as captured by the cameras 140, as might be generated by dense mapping step 318. The point cloud of FIG. 7B is semantically segmented with different classifications (colors) according to object classes in the scene as captured by the cameras 140 and as might be generated by segmented dense model step 320. For example, vegetation is colored green, utility poles are colored purple, powerlines are colored yellow, streets are colored pink, and buildings are colored red. The segmentations may then be used to estimate various physical attributes of the objects in the scene. For example, by segmenting a utility pole, additional algorithms may then be used to estimate the height and diameter of the pole as well as the locations where powerlines attach to the pole. As another example, the segmentations may also be used to infer the state of health of the pole/asset, and likeliness of it failing. For example, if the AI detects woodpecker holes in the wood pole, or a failing cross-arm, this can be used to predict whether the pole is likely to fail on its own, or in extreme events such as during an earthquake or hurricane/storm. The segmentation is a stepping stone to get to the asset's state of health.

Model analysis software 410: After construction of the various model representations, these models (comprising model data 344) can be used immediately or analyzed to extract one or more features within the representations that are important in a particular application. For example, FIGS. 7A and 7B illustrate an example segmentation of a scene into various object or asset classes and its rendering by colorizing those classes. In some examples, model analysis software 410 uses model data 344 to create more detailed model information. For example, the model analysis software 410 may use the segmented dense model data 320 to further classify and annotate the objects in the scene using data 452 from auxiliary data set 460. For example, point clouds annotated with broad classes like “utility pole” might be further segmented, classified, and labeled with additional information like pole type, transformers attached to the pole, wire gauges, etc. These additional segmentations and classification may rely on auxiliary data in, for example, other databases such as GIS databases and equipment databases.

The analyses from the model analysis software 410 may be passed back to the model construction software 310 via data information link 346 to refine and improve the model construction. For example, there may be a need to identify only poles of a certain type in a particular application. After the model analysis software 410 identifies poles of that type, the model construction software 310 may use third-party software applications. For example, the webapp may provide point cloud models in standard formats for import into computer aided design tools.

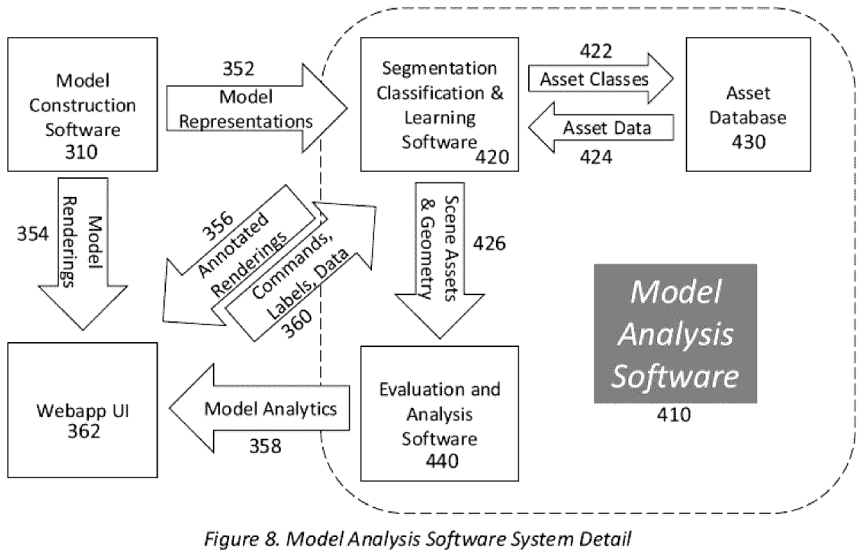

FIG. 8 illustrates a block diagram of an example model analysis software 410. After segmentation and classification of the assets and/or objects in the scene using segmentation classification and learning software 420), a database may be prompted to recall certain features of those assets. For example, if the asset is classified as a certain type of transformer used on a utility pole, the database may provide information on the physical characteristics of the transformer (such as weight and power ratings), as well as historical data (such as the age of the transformer). This asset information and the geometric information (scene asset and geometry 426) provided by the model representations is then supplied to an evaluation and analysis software 440 to further digest the scene information and provide analytics (model analytics 358) to the user.

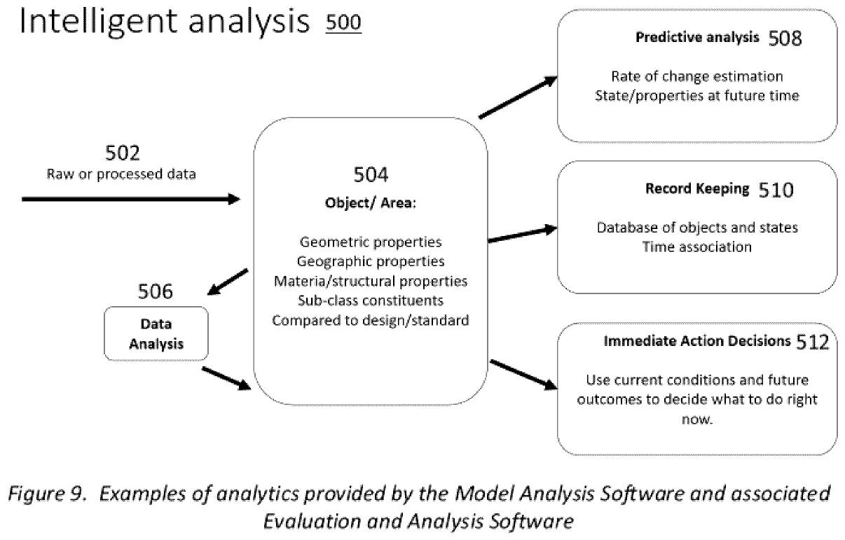

As shown in FIG. 9, the intelligent analysis 500 may use raw or processed data 502 for object/area analysis 504, data analysis 506, predictive analysis 508, record keeping analysis 510, and/or immediate action decisions 512. Examples analytics include, but are not limited to: estimation of lengths, areas, volumes, and shapes of objects; estimation of weights or forces, given identity and volume of an object; estimation of the quantity of certain types of objects withing a model representation; estimation of the material, age, health, need for maintenance, or other condition or status of an object given its geometric and surface features; delineation of different features in 2D and/or 3D and their geometry for engineering or mapping purposes; extracting key locations from objects for use in modeling applications such as pole loading analysis, etc.

Via the Webapp UI 362 or other user interface, the user may interact with the model analysis software by providing commands to indicate assets and analyses of interest. The user may also enter information (user input/output 348) to aid in the classification and analysis of assets. For example, if the transformer segmented on the utility pole has no established class with which to query a database, the user may enter the class information. If the transformer has not been automatically segmented, the user may specify the segmentation by using a software tool to manually highlight the transformer. These data and labels entered by the user may be deployed to train a machine learning component of the segmentation, classification, and learning software or to enter new data into the asset database.

Aspects of the disclosure may meet regulatory requirements including, but not limited to: FCC approval for EM standards for Wireless communication and unintentional radiators of high-frequency processors; UL and EU approvals may be required in the future; no expected performance standards in the near future; not developed under government contract; no FDA requirement; etc.

Aspects of the disclosure may use or be applied to one or more technologies including, but not limited to: robotics (control systems, localization, path planning); embedded systems (DSP, IO handling, kernel); computer vision (image filtering, compression, multi-view geometry, photogrammetry); camera layout that ensures capture of large field of view (FoV); camera synchronization and type; scene understanding; GPS/IMU/Vision localization/estimation/integration; compression and dynamic data capture; visualization of 3D models; self-learning system, machine learning, deep learning, etc.

As discussed above, easy and affordable 3D models may transform the ways to build, inspect, and maintain the human-built world. Beyond these applications, the technology described herein may enable applications like immersive reality (e.g., augmented and/or virtual reality), video games, TV and movie production, leasing and sales of real estate, 2D and 3D mapping, self-driving and assisted driving, and even the capture of everyday events that today are mostly captured using 2D cameras (e.g., cell phone). In essence, the disclosures herein allow for 3D models to become available to everyone in the same way that 2D images are available to everyone today.

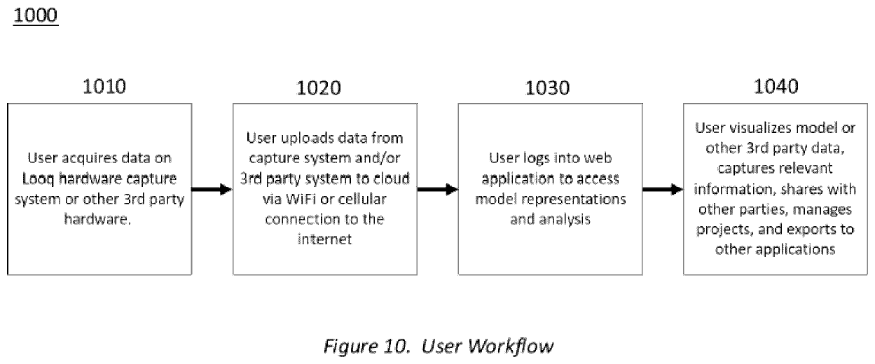

FIG. 10 illustrates an example user workflow 1000. The system and methods disclosed herein may allow construction of the model representations without requiring a user to curate data and/or tweak parameters to create accurate model representations. Because the disclosed systems and methods comprise an end-to-end hardware-software solution, the creation of the model representations may be entirely automated. Users need only capture the data (1010), upload the data (1020), inspect the model representations on a web portal (1030), and download pertinent data as needed (1040). This workflow may be further automated with the addition of capabilities and features to the model analysis software (see FIG. 1, FIG. 8, and FIG. 9).

Embodiments of the disclosure include the following technologies:

Total stations and terrestrial lidar scanners are nearly universal tools for surveyors. The stations and scanners may be situated on a tripod. These devices comprise a laser range finder, alignment optics, and a (sometimes motorized) gimbal to point the laser range finder. When used in combination with a GNSS receiver or another form of ground control, a geo-referenced set of points can be collected by pointing the laser at features of interest. Data collection may be manual or only partially automated.

Unmanned drones and manned aircraft with on-board lidar and cameras are sophisticated technology platforms provided as services for applications needing large scale 3D and 2.5D models. These platforms may be complementary to the disclosed systems and methods in that they may be useful for capturing very large areas for applications that do not require as much detail (e.g., mapping, geographic assessments).

Vehicle-mounted high-performance lidar/camera hybrid systems are sophisticated technology platforms attached to a dedicated ground vehicle (typically a large SUV) designed for high-accuracy 3D models of infrastructure captured by driving down a roadway.

Photographic mapping systems are systems that deploy two or more cameras as a single unit (e.g., 360 cameras) and are used in mapping applications, panoramic image/video capture, and some 3D representations. The disclosed systems and methods enable automation of the model construction and analysis.

Use cases for the disclosed systems and methods, and corresponding product implementations, include, but are not limited to: powerline/pole inspection, maintenance, construction; underground powerline maintenance and construction; power generation inspection, maintenance, construction; solar array fields and wind farms inspection, maintenance, construction; vehicle charging infrastructure inspection, maintenance, construction; general land surveying; general infrastructure inspection, maintenance, construction; general building inspection, maintenance, construction; bridge inspection, maintenance, construction; pipeline inspection, maintenance, construction; roadway inspection, maintenance, construction; waterway inspection, maintenance, construction; dam inspection, maintenance, construction; insurance; industrial plant inspection, maintenance, construction; oil and gas plant inspection, maintenance, construction; mining; scene capture and content production for movies/TV/videos/games/augmented reality/virtual reality; real estate model capture for sales, marketing, and documentation; insurance claims evaluation and asset inventory; facilities management and asset inventory; forestry plotting, DBM measurement, and feature classification; agricultural management; custom site-walk generation; asset survey for disaster relief; asset identification and management for government or commercial GIS database updates; etc.

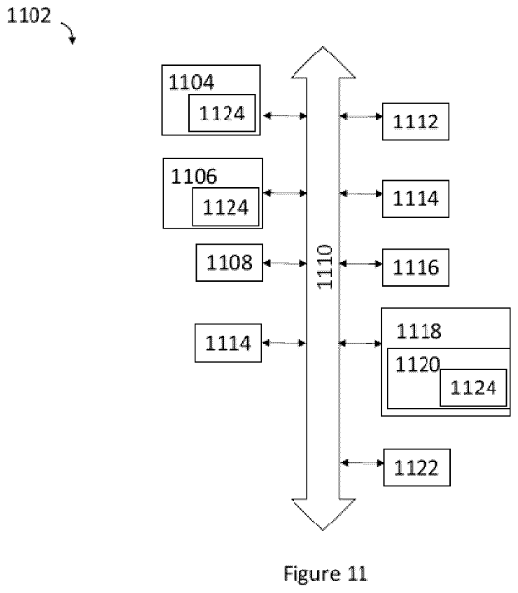

The methods discussed above may be implemented by a system. FIG. 11 illustrates a block diagram of an exemplary system 1102, according to embodiments of the disclosure. The system may be a machine such as a computer, within which a set of instructions, causes the machine to perform any one of the steps and operations discussed herein, according to embodiments of the disclosure. In some embodiments, the machine can operate as a standalone device or may be connected (e.g., networked) to other machines. In a networked configuration, the machine may operate in the capacity of a server or a client machine in a server-client network environment, or as a peer machine in a peer-to-peer (or distributed) network environment. The machine can be a personal computer (PC), a tablet PC, a set-top box (STB), a personal digital assistant (PDA), a cellular telephone, a web appliance, a network router, a switch or bridge, or any machine capable of executing a set of instructions (sequential or otherwise) that specify actions to be taken by that machine. A mobile device such as a PDA or a cellular phone may also include an antenna, a chip for sending and receiving radio frequency transmissions and communicating over cellular phone WAP and SMS networks, and a built-in keyboard. Further, while only a single machine is illustrated, the term “machine” shall also be taken to include any collection of machines that individually or jointly execute a set (or multiple sets) of instructions to perform any one of the methodologies discussed herein.

The exemplary computer 1102 includes a processor 1104 (e.g., a central processing unit (CPU), a graphics processing unit (GPU), or both), a main memory 1106 (e.g., read-only memory (ROM), flash memory, dynamic random access memory (DRAM) such as synchronous DRAM (SDRAM) or Rambus DRAM (RDRAM), etc.), and a static memory 1108 (e.g., flash memory, static random access memory (SRAM), etc.), which can communicate with each other via a bus 1110.

The computer 1102 may further include a video display 1112 (e.g., a liquid crystal display (LCD) or a cathode ray tube (CRT)). The computer 1102 also includes an alpha-numeric input device 1114 (e.g., a keyboard), a cursor control device 1116 (e.g., a mouse), a disk drive unit 1118, a signal generation device 1120 (e.g., a speaker), and a network interface device 1122.

The drive unit 1118 includes a machine-readable medium 1120 on which is stored one or more sets of instructions 1124 (e.g., software) embodying any one or more of the methodologies or functions described herein. The software may also reside, completely or at least partially, within the main memory 1106 and/or within the processor 1104 during execution thereof by the computer 1102, the main memory 1106 and the processor 1104 also constituting machine-readable media. The software may further be transmitted or received over a network 1104 via the network interface device 1122.

While the machine-readable medium 1120 is shown in an exemplary embodiment to be a single medium, the term “non-transitory computer-readable medium” should be taken to include a single medium or multiple media (e.g., a centralized or distributed database and/or associated caches and servers) that store the one or more sets of instructions. The term “machine-readable medium” shall also be taken to include any medium that is capable of storing, encoding, or carrying a set of instructions for execution by the machine and that cause the machine to perform any one or more of the methodologies of the present invention. The term “machine-readable medium” shall accordingly be taken to include, but not be limited to, solid-state memories, optical and magnetic media, and carrier wave signals.

Although examples of this disclosure have been fully described with reference to the accompanying drawings, it is to be noted that various changes and modifications will become apparent to those skilled in the art. Such changes and modifications are to be understood as being included within the scope of examples of this disclosure as defined by the appended claims.

1. A system for creating a 3D model representation of a scene, the system comprising:
capture system hardware configured to capture data of the scene using at least a plurality of cameras;
capture system software configured to control the capture system hardware by determining one or more parameters for capturing the data;
model construction software configured to construct one or more model representations using the captured data and information about the capture system hardware; and
model analysis software configured to extract one or more features of the one or more model representations and create the 3D model representation of the scene, wherein the 3D model representation of the scene comprises the one or more extracted features.

2. The system of claim 1, wherein the capture system hardware comprises:
a camera frame assembly that maintains positions and orientations of the plurality of cameras with respect to each other; and
a time controller that synchronizes capturing of image data by the plurality of cameras.

3. The system of claim 2, wherein the model construction software is configured to:
build one or more maps representative of location and orientation of the system within the scene wherein the one or more maps are used to create the 3D model representation of the scene.

4. The system of claim 1, wherein the plurality of cameras comprises a first camera facing forward, a second camera facing upward, a third camera facing left, and a fourth camera facing right.

5. The system of claim 1, further comprising:
a mount configured to attach the capture system hardware to a handle or a pole; and
a display configured to be mounted on the rear of the capture system hardware.

6. The system of claim 1, further comprising a plurality of lights surrounding the plurality of cameras, the plurality of lights configured to illuminate the scene during image capture.

7. The system of claim 6, wherein the capture system hardware comprises a time controller configured to control the plurality of lights during image capture based on one or more of: a brightness of the scene, a motion of the scene, a battery power, and user experience.

8. The system of claim 1, further comprising: one or more location sensors configured to determine location and orientation information of the system, wherein the one or more location sensors comprise one or more of: a satellite geolocation sensor (GPS) or an inertial measurement unit (IMU) sensor.

9. The system of claim 1, comprising an onboard computer configured for image capture, sensor data capture, and processing image and sensor data.

10. The system of claim 1, wherein the capture system software is configured to:
receive input data comprising one or more of: sensor inputs, user inputs, and prior image data; and
control one or more of the plurality of cameras and one or more lights during image capture based on the received input data.

11. The system of claim 1, further comprising:
a transceiver configured to receive information from a WiFi connection, a cellular connection, or real-time GPS correction services,
wherein the received information is used by the capture system software to improve estimations of locations and orientations of the plurality of cameras.

12. The system of claim 1, wherein the capture system software is configured to provide input for controlling movements of a robot, or for providing information to an operator of the robot for controlling the movements of the robot.

13. The system of claim 1, wherein the model construction software comprises a feature extraction algorithm configured to identify features within images represented by the captured data.

14. The system of claim 1, wherein the model construction software comprises a feature matching algorithm configured to identify common features in different images of the scene.

15. The system of claim 14, wherein the model construction software comprises a mapping algorithm configured to:
receive the identified common features of the scene and the information corresponding to the captured data;
determine 3D positions and orientations of the plurality of cameras during image capture; and
determine 3D positions of the identified common features of the scene.

16. The system of claim 15, wherein the model construction software constructs a 3D point cloud representation of the scene from the 3D positions of the identified common features of the scene model construction software;
wherein the model construction software is further configured to:
construct one or more projected 2D representations using the 3D point cloud representation and the captured data; or
identify and match common features across captured images using the 3D point cloud representation and information about the capture system hardware during image capture.

17. The system of claim 1, wherein the model construction software comprises a 2D image segmentation and classification algorithm that identifies objects in 2D images and labels pixels of the 2D images with information pertaining to features of the identified objects, wherein the pixel labels are propagated to corresponding points in a 3D point cloud representation of the scene.

18. The system of claim 1, wherein the model analysis software is configured to receive user input, wherein the extraction of the one or more features of the one or more model representations is based on the user input.

19. The system of claim 17, wherein the user input comprises inputs related to one or more of: segmentation, classification of features, labeling, feature information, or object information.

20. A computer-implemented method for creating a 3D model representation of a scene, the method comprising:
capturing data of the scene using a plurality of cameras of a capture system hardware;
receiving information about the capture system hardware;
constructing one or more model representations using the captured data and received information;
extracting one or more features of the one or more model representations; and
creating the 3D model representation of the scene, wherein the 3D model representation of the scene comprises the one or more extracted features.
